(19) United States
(12) Patent Application Publication
(10) Pub. No.: US 2018/0238751 A1
(43) Pub. Date: Aug. 23, 2018

(54) PIEZOELECTRIC DEFLECTION SENSOR

(71) Applicant: Murata Manufacturing Co., Ltd., Nagaokakyo-shi (JP)

(72) Inventors: Shingo CHIDA, Nagaokakyo-shi (JP); Yuya GENMEI, Nagaokakyo-shi (JP); Masayuki ICHIMARU, Nagaokakyo-shi (JP)

(21) Appl. No.: 15/955,729

(22) Filed: Apr. 18, 2018

Related U.S. Application Data
(63) Continuation of application No. PCT/JP2016/082318, filed on Oct. 31, 2016.

(30) Foreign Application Priority Data
Nov. 13, 2015 (JP) 2015-222589

(51) Int. Cl. G01L 1/16; H01L 41/053; H01L 41/113; H01L 41/083; H01L 41/187; H01L 41/047; G01B 7/16

(52) U.S. Cl. CPC G01L 1/16; H01L 41/053; H01L 41/1132; G01B 7/16; H01L 41/1876; H01L 41/0477; H01L 41/083

(57) ABSTRACT

A piezoelectric deflection sensor includes a first package substrate bonded onto a first principal surface of a first piezoelectric plate via a first bonding material layer, and a second package substrate bonded onto a second principal surface of the first piezoelectric plate via a second bonding material layer. A second electrode is provided on a principal surface of the first piezoelectric plate, and first and second segmented electrodes are provided on the other. A polarization axis direction of the first piezoelectric plate is parallel or substantially parallel to the first and second principal surfaces and is a direction along any side of the first piezoelectric plate. A groove extending in a direction intersecting the polarization axis direction in the first package substrate is provided at a position overlapping with at least a portion of a first electrode non-formation region between the first and second segmented electrodes in plan view.

### CROSS REFERENCE TO RELATED APPLICATIONS

This application claims the benefit of priority to Japanese Patent Application No. 2015-222589 filed on Nov. 13, 2015 and is a Continuation Application of PCT Application No. PCT/JP2016/082318 filed on Oct. 31, 2016. The entire contents of each application are hereby incorporated herein by reference.

### BACKGROUND OF THE INVENTION

### 1. Field of the Invention

The present invention relates to a piezoelectric deflection sensor to detect a deflection of a substrate or the like.

### 2. Description of the Related Art

As a sensor which detects a deflection of a substrate or the like, there is conventionally known a piezoelectric sensor using a d31 mode, for example, as disclosed in Japanese Patent Laid-Open No. 62-156503.

A piezoelectric sensor disclosed in Japanese Patent Laid-Open No. 62-156503 has a bimorph structure including an upper layer piezoelectric thin film and a lower layer piezoelectric thin film. When it detects a deflection, outputs of the upper layer and the lower layer are measured, and for example, the output of the upper layer is corrected. Next, the corrected output of the upper layer and the output of the lower layer are added. Thus, upper layer charge and lower layer charge that arise from the pyroelectric effect of the piezoelectric sensor are offset.

However, with the piezoelectric sensor disclosed in Japanese Patent Laid-Open No. 62-156503, a measurement device which measures the outputs of the upper layer and the lower layer and a correction circuit which corrects the output of the upper layer or the lower layer must be provided. Accordingly, detection efficiency has been poor.

### SUMMARY OF THE INVENTION

Preferred embodiments of the present invention provide piezoelectric deflection sensors capable of detecting a deflection of a substrate on which a piezoelectric deflection sensor is provided with high detection efficiency.

A piezoelectric deflection sensor according to a preferred embodiment of the present invention includes a piezoelectric element including a first piezoelectric plate including a first principal surface and a second principal surface opposing the first principal surface, a plan shape of the first piezoelectric plate being rectangular, substantially rectangular, square, or substantially square, a polarization axis direction of the first piezoelectric plate being parallel or substantially parallel to the first and second principal surfaces and being a direction along any side thereof; a first electrode provided on the first principal surface of the first piezoelectric plate; and a second electrode provided on the second principal surface of the first piezoelectric plate; a first package substrate stacked on the first principal surface of the piezoelectric element; a second package substrate stacked on the second principal surface of the piezoelectric element; a first bonding material layer bonding the first package substrate onto the first principal surface of the first piezoelectric plate; and a second bonding material layer bonding the second package substrate onto the second principal surface of the first piezoelectric plate, wherein one of the first electrode and the second electrode includes first and second segmented electrodes provided along the polarization axis direction across a first electrode non-formation region extending in a direction intersecting the polarization axis direction, and the other of the first electrode and the second electrode opposes the first and second segmented electrodes and the first electrode non-formation region across the first piezoelectric plate, and a groove extending in a direction intersecting the polarization axis direction in the first package substrate is provided at a position overlapping with at least a portion of the first electrode non-formation region in plan view.

In a piezoelectric deflection sensor according to a preferred embodiment of the present invention, the first electrode non-formation region extends in a direction perpendicular or substantially perpendicular to the polarization axis direction. In this case, a deflection is able to be detected with higher efficiency.

In a piezoelectric deflection sensor according to a preferred embodiment of the present invention, the groove extends in a direction perpendicular or substantially perpendicular to the polarization axis direction. In this case, a deflection of a substrate on which the piezoelectric deflection sensor is provided is able to be detected with higher sensitivity.

In a piezoelectric deflection sensor according to a preferred embodiment of the present invention, the first and second segmented electrodes are provided on the first principal surface of the first piezoelectric plate.

In a piezoelectric deflection sensor according to a preferred embodiment of the present invention, the first and second segmented electrodes are provided on the second principal surface of the first piezoelectric plate.

In a piezoelectric deflection sensor according to a preferred embodiment of the present invention, the groove is positioned at a center or an approximate center of the first package substrate in the polarization axis direction. In this case, a deflection of a substrate on which the piezoelectric deflection sensor is provided is able to be detected with higher sensitivity.

In a piezoelectric deflection sensor according to a preferred embodiment of the present invention, the groove extends to the piezoelectric element from the first package substrate.

In a piezoelectric deflection sensor according to a preferred embodiment of the present invention, the groove extends to the second package substrate.

In a piezoelectric deflection sensor according to a preferred embodiment of the present invention, a second piezoelectric plate stacked on the second principal surface of the first piezoelectric plate is provided, a polarization axis direction of the second piezoelectric plate being a reverse direction to the polarization axis direction of the first piezoelectric plate, wherein third and fourth segmented electrodes extending across a second electrode non-formation region in the polarization axis direction are provided on a surface of the second piezoelectric plate on the second package substrate side. In this case, sensitivity of a deflection sensor is able to be further improved.

In accordance with piezoelectric deflection sensors according to preferred embodiments of the present invention, detection efficiency of a deflection of a substrate on which the piezoelectric deflection sensor is provided is able to be improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an exploded perspective view of a piezoelectric deflection sensor according to a first preferred embodiment of the present invention from which external electrodes are removed.

FIG. 2 is a schematic cross-sectional elevation view showing a state in which the piezoelectric deflection sensor according to the first preferred embodiment of the present invention is provided on a substrate.

FIGS. 3A and 3B are a schematic plan view and a schematic plan view in which a first piezoelectric plate is made translucent for explaining a second electrode and a first electrode on a second principal surface and a first principal surface of the first piezoelectric plate used in the piezoelectric deflection sensor according to the first preferred embodiment of the present invention.

FIG. 4 is a schematic cross-sectional elevation view showing a state in which a piezoelectric deflection sensor according to a second preferred embodiment of the present invention is provided on a substrate.

FIG. 5 is an exploded perspective view of a piezoelectric deflection sensor according to a third preferred embodiment of the present invention.

FIG. 6 is a schematic cross-sectional elevation view showing a state in which the piezoelectric deflection sensor according to the third preferred embodiment of the present invention is provided on a substrate.

FIG. 7 is an exploded perspective view of a piezoelectric deflection sensor according to a fourth preferred embodiment of the present invention.

FIG. 8 is a schematic cross-sectional elevation view showing a state in which the piezoelectric deflection sensor according to the fourth preferred embodiment of the present invention is provided on a substrate.

FIG. 9 is a bottom view of a first package substrate for explaining a modification of a groove in a piezoelectric deflection sensor according to a preferred embodiment of the present invention.

FIG. 10 is a bottom view of the first package substrate for explaining another modification of the groove in a piezoelectric deflection sensor according to a preferred embodiment of the present invention.

### DETAILED DESCRIPTION OF THE PREFERRED EMBODIMENTS

Hereafter, the present invention will be clarified by describing specific preferred embodiments of the present invention with reference to the drawings.

It is pointed out that preferred embodiments disclosed in the present specification are exemplary and partial substitutions or combinations between difference preferred embodiments may occur.

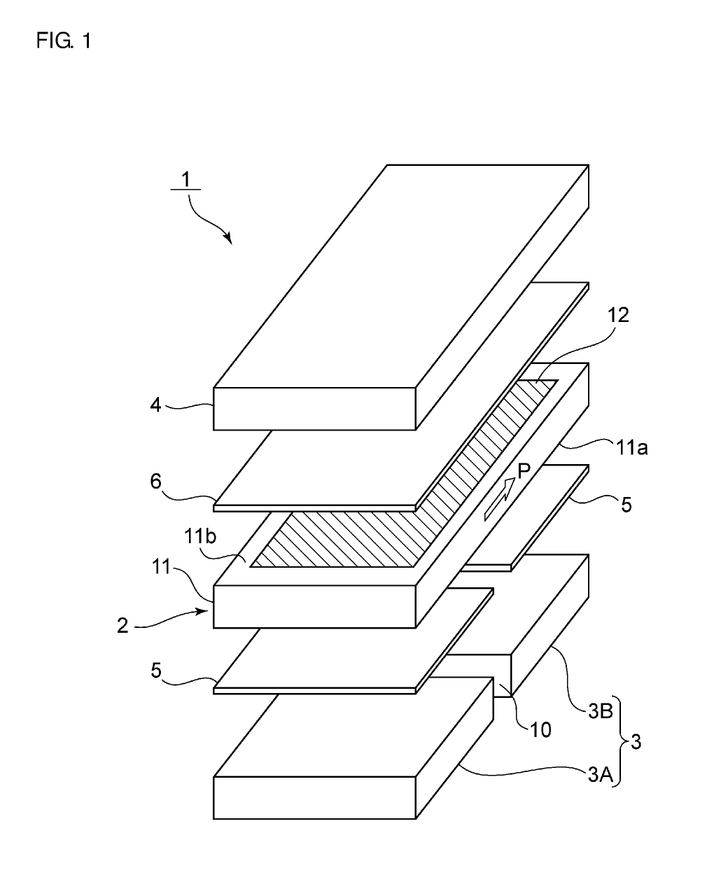

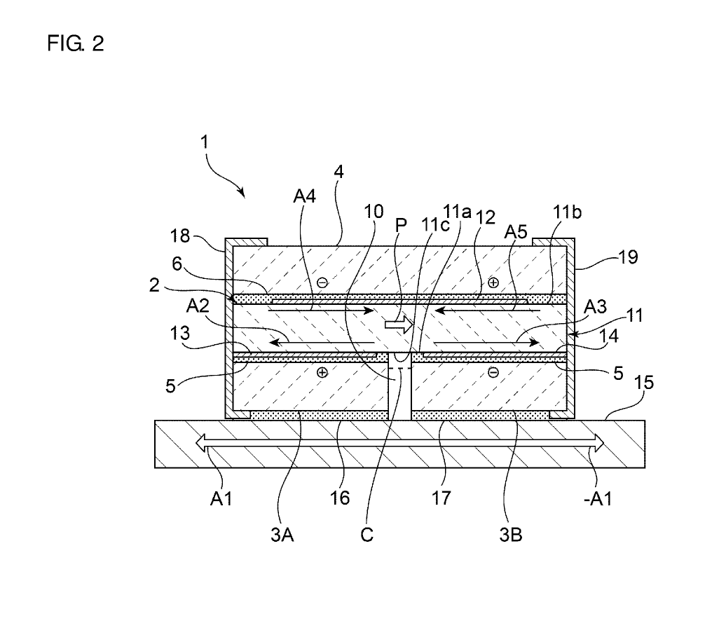

FIG. 1 is an exploded perspective view of a piezoelectric deflection sensor according to a first preferred embodiment of the present invention from which external electrodes are removed. FIG. 2 is a schematic cross-sectional elevation view showing a state in which the piezoelectric deflection sensor according to the first preferred embodiment is provided on a substrate.

As shown in FIG. 1, a piezoelectric deflection sensor includes a piezoelectric element 2, first and second package substrates 3 and 4, and first and second bonding material layers 5 and 6. The piezoelectric element 2 includes a first piezoelectric plate 11 having a rectangular, substantially rectangular, square, or substantially square plan shape. In the present preferred embodiment, the first piezoelectric plate 11 preferably has a rectangular or substantially rectangular plan shape. The first piezoelectric plate 11 is preferably made of piezoelectric ceramics, such as PZT or a piezoelectric single crystal, for example.

A polarization axis direction P of the first piezoelectric plate 11 is along a lengthwise direction of the first piezoelectric plate 11. That is, the polarization axis direction P is parallel or substantially parallel to a first principal surface 11a and a second principal surface 11b and in direction along the sides extending in the lengthwise direction of the rectangular or substantially rectangular shape.

The piezoelectric deflection sensor 1 is provided on a substrate described below from the first package substrate 3 side. Accordingly, the package substrate that is positioned below the piezoelectric plate 11 is regarded as the first package substrate 3, and in the first piezoelectric plate 11, the principal surface on the side that is stacked on the first package substrate 3, that is, the lower surface is regarded as the first principal surface 11a.

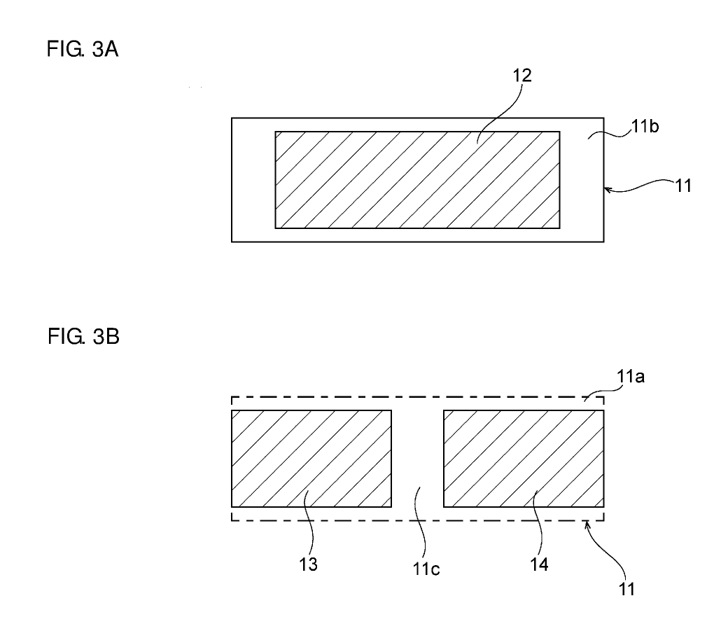

As shown in FIG. 1 and FIG. 3A, a second electrode 12 is provided on the second principal surface 11b of the first piezoelectric plate 11. Moreover, as shown in FIG. 3B, first and second segmented electrodes 13 and 14 are provided on the first principal surface 11a thereof. A first electrode opposing the second electrode 12 includes the first segmented electrode 13 and the second segmented electrode 14. The second electrode 12 and the first and second segmented electrodes 13 and 14 are preferably made of metal such as Cu, Ag, Al or Au or alloy thereof, for example.

The first and second segmented electrodes 13 and 14 are provided so as to oppose the second electrode 12 across the first piezoelectric plate 11.

Moreover, as shown in FIG. 3B, the first segmented electrode 13 and the second segmented electrode 14 are separated from each other in the polarization axis direction P across a first electrode non-formation region 11c. The first electrode non-formation region 11c means a region which is on the first principal surface 11a of the first piezoelectric plate 11 and is interposed between the first segmented electrode 13 and the second segmented electrode 14. The first electrode non-formation region 11c extends in a direction intersecting the polarization axis direction P, and in the present preferred embodiment, in a direction perpendicular or substantially perpendicular to the polarization axis direction P.

In FIG. 1, the lengthwise dimension of the second electrode 12, that is, the dimension thereof along the polarization axis direction P is denoted as the length, and the dimension thereof in the direction perpendicular or substantially perpendicular to the polarization axis direction P is denoted as the width. The width of the second electrode 12 is preferably narrower than the width of the first piezoelectric plate 11. That is, one widthwise end and the other widthwise end of the second electrode 12 are positioned inwardly of one widthwise end and the other widthwise end of the first piezoelectric plate 11. One widthwise end and the other widthwise end of each of the first segmented electrode 13 and the second segmented electrode 14 is also positioned inwardly of one widthwise end and the other widthwise end of the first principal surface 11a of the first piezoelectric plate 11 in the widthwise direction.

One lengthwise end and the other lengthwise end of the second electrode 12 are positioned inwardly of one lengthwise end and the other lengthwise end of the first piezoelectric plate 11.

As shown in FIG. 1, the first package substrate 3 is bonded to the piezoelectric element 2, more specifically, bonded onto the first principal surface 11a side of the first piezoelectric plate 11 via the first bonding material layer 5. The first package substrate 3 is segmented into a first segmented package substrate 3A and a second segmented package substrate 3B across a groove 10.

The dimensions of the first segmented package substrate 3A and the second segmented package substrate 3B along the widthwise direction of the piezoelectric element 2 are preferably the same or substantially the same as that of the piezoelectric element 2.

The groove 10 extends in a direction intersecting the polarization axis direction P, and in the present preferred embodiment, in a direction perpendicular or substantially perpendicular to the polarization axis direction P at a position overlapping with at least a portion of the first electrode non-formation region 11c in plan view.

The groove 10 extends over the entire width of the first package substrate 3 in the widthwise direction. Accordingly, the first package substrate 3 is segmented into the first segmented package substrate 3A and the second segmented package substrate 3B. The first package substrate 3 is preferably made of insulative ceramics, such as alumina or magnesium titanate, for example. However, the first package substrate 3 may be made of semiconductor ceramics, piezoelectric ceramics or other suitable materials other than the insulative ceramics.

The plan shape of the second package substrate 4 is the same or substantially the same as that of the first piezoelectric plate 11. The second package substrate 4 may preferably also be made of the same or similar material to that of the first package substrate 3. The second package substrate 4 is bonded onto the second principal surface 11b of the first piezoelectric plate 11 with the second bonding material layer 6.

The first and second bonding material layers 5 and 6 are preferably made of adhesive agents, such as an epoxy-based adhesive agent, for example. The adhesive agents used are not specifically limited.

Deflection detection operation of the piezoelectric deflection sensor 1 is described with reference to FIG. 2. A first external electrode 18 is provided on one lengthwise end surface of a stacked body including the piezoelectric element 2 and the first and second package substrates 3 and 4. The first external electrode 18 is electrically connected to the first segmented electrode 13. A second external electrode 19 is provided on the other lengthwise end surface of the stacked body. The second external electrode 19 is electrically connected to the second segmented electrode 14. By electrical connections to the outside using the first and second external electrodes 18 and 19, an output due to a deflection is able to be detected.

As shown in FIG. 2, the piezoelectric deflection sensor 1 is provided on a substrate 15 in a face-to-face manner. More specifically, the piezoelectric deflection sensor 1 is provided on the substrate 15 in a face-to-face manner via bonding material layers 16 and 17. As the bonding material layers 16 and 17, bonding materials, such as an adhesive agent and solder, for example, may preferably be used.

The first package substrate 3 of the piezoelectric deflection sensor 1 is bonded to the center or approximate center of the substrate 15 via the bonding material layers 16 and 17.

It is assumed that the substrate 15 is deflected as indicated by arrows A1 and −A1. In this case, the substrate 15 expands in the direction indicated by the arrow A1 on the one lengthwise end side relative to the portion below the groove 10, and expands as indicated by the arrow −A1 on the other lengthwise end side. When such a deflection occurs, stress due to the deflection is exerted on the first piezoelectric plate 11 via the first package substrate 3. In this stage, above a portion of the substrate 15 that expands in the direction indicated by the arrow A1, the first segmented package substrate 3A expands in the same direction. Accordingly, the first piezoelectric plate 11 expands in the direction indicated by an arrow A2 at a position above the first segmented package substrate 3A. As a result, as its reaction, a layer portion of the first piezoelectric plate 11 on the second principal surface 11b side expands in the reverse direction to that of the arrow A2, that is, in the direction indicated by an arrow A4.

On the second segmented package substrate 3B side, the substrate 15 expands in the direction indicated by the arrow −A1. Accordingly, a layer of the first piezoelectric plate 11 on the first principal surface 11a side expands in the direction indicated by an arrow A3 on a portion thereof positioned on the second segmented package substrate 3B. On the other hand, as its reaction, a layer thereof on the second principal surface 11b side expands in the direction indicated by an arrow A5.

Accordingly, in the first piezoelectric plate 11, stresses in reverse directions arise in the portion above the first segmented package substrate 3A and in the portion above the second segmented package substrate 3B. Therefore, a positive charge is generated in the first segmented electrode 13, and a negative charge is generated in the second segmented electrode 14. In the second electrode 12, a negative charge is generated above the portion expanding in the aforementioned direction indicated by the arrow A4, and a positive charge is generated above the portion expanding in the direction indicated by the arrow A5. Accordingly, potentials generated on the one lengthwise end side and the other end side of the first piezoelectric plate 11 are connected in series. Therefore, potentials in accordance with a deflection of the implementation substrate 15 are output from the first segmented electrode 13 and the second segmented electrode 14.

Further, since the groove 10 is provided, stress due to the deflection of the substrate 15 is efficiently exerted on the first piezoelectric plate 11. Accordingly, detection efficiency is improved, and sensitivity is improved. Since the deflection is detected with the outputs of the first and second segmented electrodes 13 and 14, a complex correction circuit is not required.

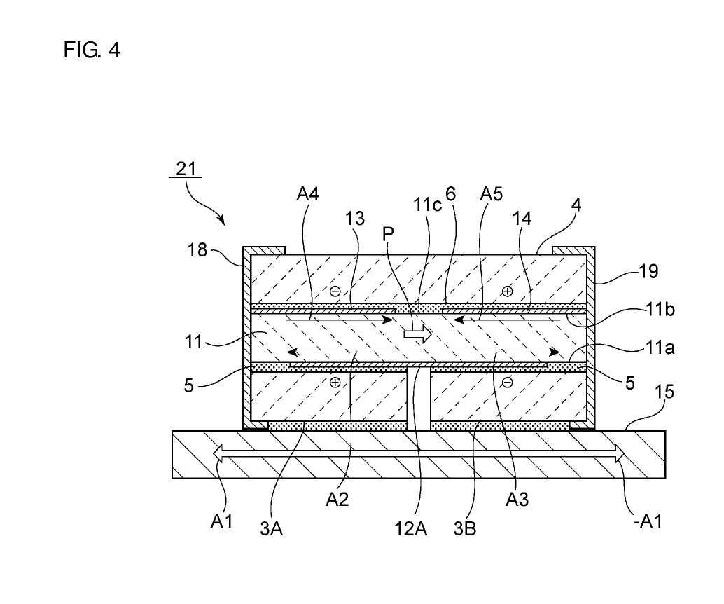

FIG. 4 is a schematic cross-sectional elevation view showing a state in which a piezoelectric deflection sensor according to a second preferred embodiment of the present invention is provided on a substrate. In a piezoelectric deflection sensor 21 according to the second preferred embodiment, a first electrode 12A is provided on the first principal surface 11a. The first and second segmented electrodes 13 and 14 are provided on the second principal surface 11b. Accordingly, the first electrode non-formation region 11c is provided on the second principal surface 11b.

The piezoelectric deflection sensor 21 according to the second preferred embodiment is similar in the remaining configuration to the piezoelectric deflection sensor 1 according to the first preferred embodiment.

The first electrode 12A may be provided on the first principal surface 11a and the first and second segmented electrodes 13 and 14 may be provided on the second principal surface 11b side.

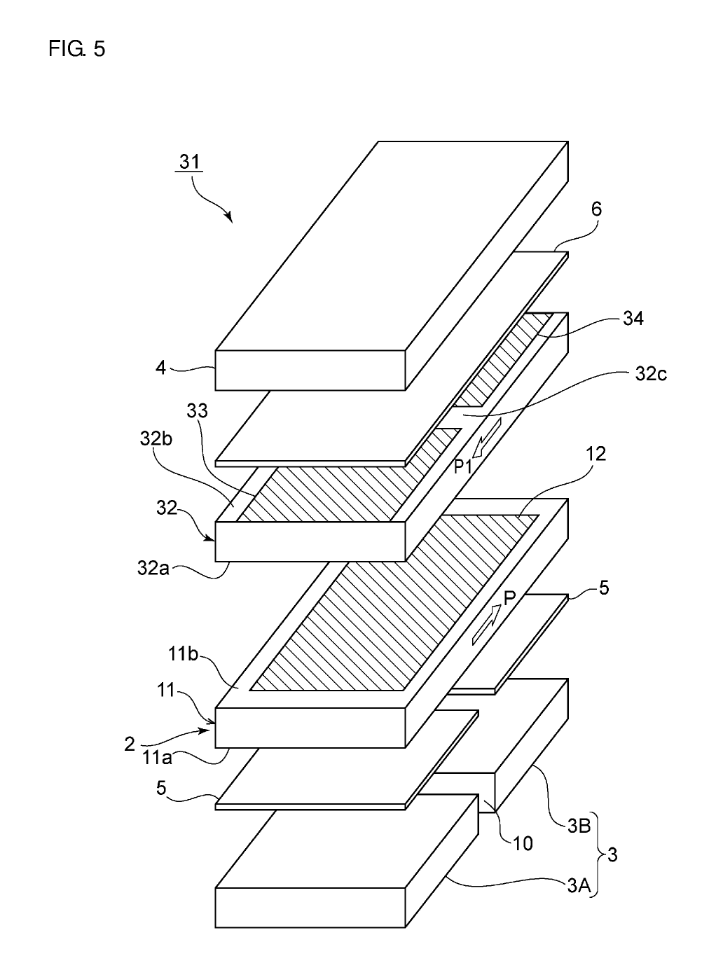

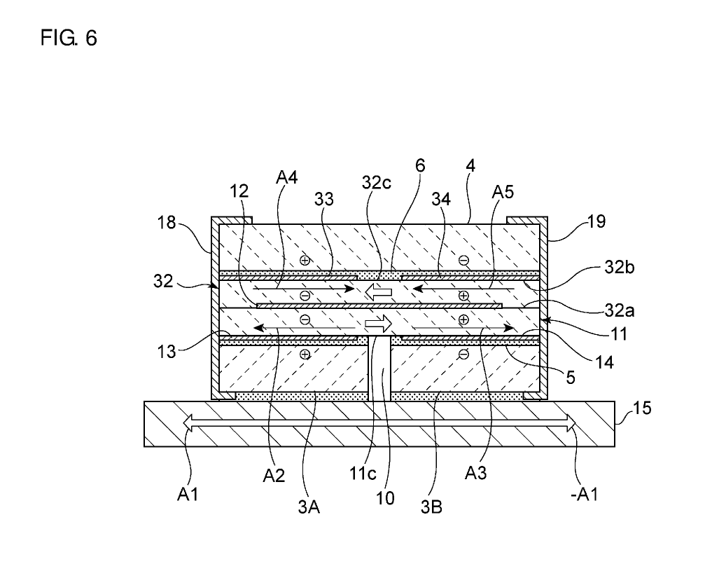

FIG. 5 is an exploded perspective view of a piezoelectric deflection sensor according to a third preferred embodiment of the present invention. FIG. 6 is a schematic cross-sectional elevation view showing a state in which the piezoelectric deflection sensor according to the third preferred embodiment is provided on a substrate.

In a piezoelectric deflection sensor 31 according to the third preferred embodiment, a second piezoelectric plate 32 is stacked on the first piezoelectric plate 11. The second piezoelectric plate 32 is preferably made of the same piezoelectric material as that of the first piezoelectric plate 11. In the second piezoelectric plate 32, a polarization axis direction P1 extends in the reverse direction to the polarization axis direction P of the first piezoelectric plate 11. The first piezoelectric plate 11 and the second piezoelectric plate 32 may preferably be integrated by a suitable method. For example, the first piezoelectric plate 11 and the second piezoelectric plate 32 may preferably be bonded together with an adhesive agent, such as epoxy-based resin, for example.

The second piezoelectric plate 32 includes a first principal surface 32a on the first piezoelectric plate 11 side, and a second principal surface 32b on the second package substrate 4 side. Third and fourth segmented electrodes 33 and 34 are provided on the second principal surface 32b. The third and fourth segmented electrodes 33 and 34 are provided at positions overlapping with the first and second segmented electrodes 13 and 14 in plan view. Accordingly, a second electrode non-formation region 32c is provided between the third and fourth segmented electrodes 33 and 34.

The piezoelectric deflection sensor 31 preferably is substantially the same as the piezoelectric deflection sensor 1 of the first preferred embodiment except that the structure of the piezoelectric element is configured as described above.

It is assumed that the substrate 15 is deflected similarly to the case in FIG. 2. In such a case, the first piezoelectric plate 11 expands in the direction of the arrow A2 with stress in the direction indicated by the arrow A2 arising therein, above the first segmented package substrate 3A. The second piezoelectric plate 32 expands in the direction of the arrow A4. Meanwhile, the first piezoelectric plate 11 expands in the direction of the arrow A3, and the second piezoelectric plate 32 expands in the direction indicated by the arrow A5, above the second segmented package substrate 3B.

Accordingly, as indicated by signs in FIG. 6, a positive charge is generated in the first segmented electrode 13. A negative charge is generated in the second segmented electrode 14. Above the first segmented package substrate 3A, a negative charge is generated in the second electrode 12 which is a floating electrode, and a positive charge is generated in the third segmented electrode 33. Moreover, above the second segmented package substrate 3B, a positive charge is generated in the second electrode 12, and a negative charge is generated in the fourth segmented electrode 34.

In the present preferred embodiment, the first segmented electrode 13 and the third segmented electrode 33 are electrically connected to each other with the first external electrode 18. The second segmented electrode 14 and the fourth segmented electrode 34 are electrically connected to each other with the second external electrode 19.

Accordingly, outputs in accordance with a deflection of the substrate 15 are able to be transmitted from the first and second external electrodes 18 and 19. Also in the present preferred embodiment, since the groove 10 is provided, detection efficiency is able to be improved. Furthermore, since the structure including the first and second piezoelectric plates 11 and 32 stacked is provided, sensitivity is able to be further improved.

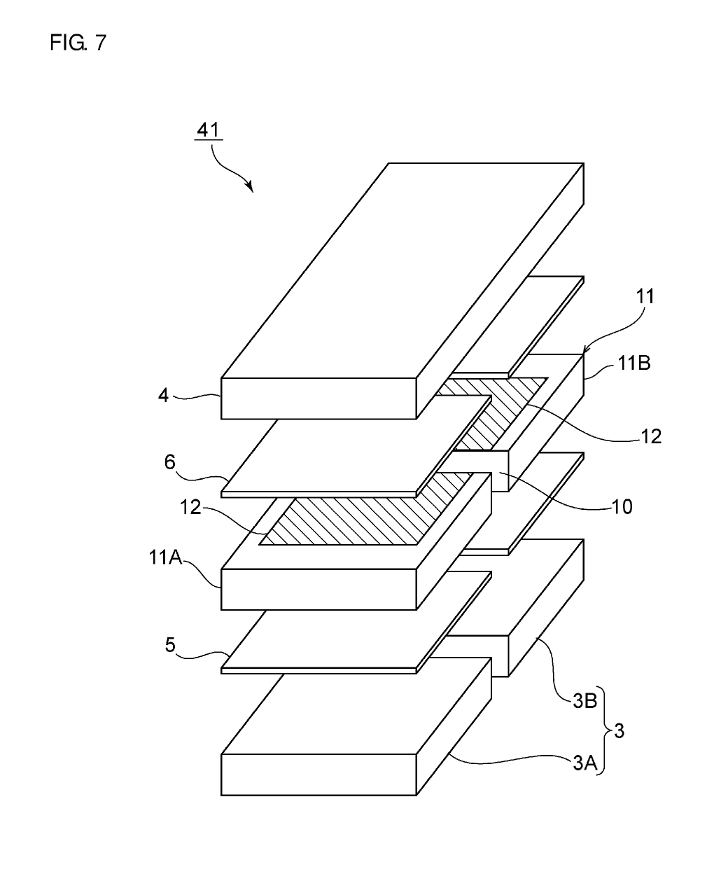

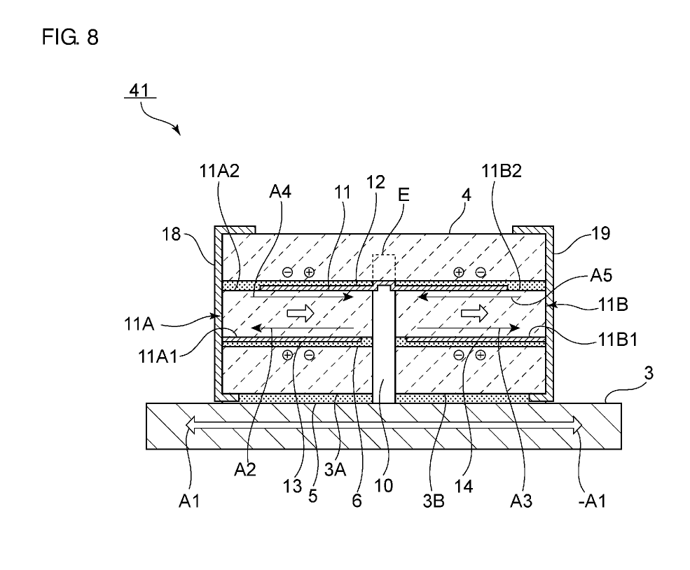

FIG. 7 is an exploded perspective view of a piezoelectric deflection sensor according to a fourth preferred embodiment of the present invention. FIG. 8 is a schematic cross-sectional elevation view showing a state in which the piezoelectric deflection sensor according to the fourth preferred embodiment is provided on a substrate.

In the piezoelectric deflection sensor 41 according to the fourth preferred embodiment, the first piezoelectric plate 11 is segmented by the groove 10. As shown in FIG. 8, the groove 10 extends upward beyond the first package substrate 3 and is provided so as to segment the first piezoelectric plate 11. The groove 10 may extend to the first piezoelectric plate 11 side beyond the first package substrate 3. Moreover, the groove 10 may extend to the second package substrate 4 as indicated by the broken line E in FIG. 8.

Since the groove 10 is provided in the piezoelectric deflection sensor 41, the first piezoelectric plate 11 is segmented into a first segmented piezoelectric plate 11A and a second segmented piezoelectric plate 11B. The first segmented electrode 13 is provided on a first principal surface 11A1 of the first segmented piezoelectric plate 11A. The second segmented electrode 14 is provided on a first principal surface 11B1 of the second segmented piezoelectric plate 11B. The second electrode 12 is provided on a second principal surface 11A2 of the first segmented piezoelectric plate 11A. The second electrode 12 further extends to a second principal surface 11B2 of the second segmented piezoelectric plate 11B across on the lower surface of the second package substrate 4. The second electrode 12 that is on the second principal surface 11B2 opposes the second segmented electrode 14 across the second segmented piezoelectric plate 11B.

The piezoelectric deflection sensor 41 is similar to the piezoelectric deflection sensor 1 except that the groove 10 is provided so as to segment the first piezoelectric plate. Accordingly, in the present preferred embodiment, when the substrate 15 is deflected, stresses arise in the directions indicated by the arrows A2, A3, A4 and A5 in the first and second segmented piezoelectric plates 11A and 11B. Therefore, charges are generated as indicated by positive and negative signs in the figure. Therefore, outputs in accordance with a deflection of the substrate 15 are able to be transmitted from the first and second external electrodes 18 and 19 connected to the first and second segmented electrodes 13 and 14. In particular, since the groove 10 extends to the first piezoelectric plate 11, detection efficiency is able to be improved, and sensitivity is able to be further improved.

When the groove 10 extends to the second package substrate 4 as indicated by the broken line E in FIG. 8, the second electrode 12 may electrically connect an electrode portion on the first segmented piezoelectric plate 11A and an electrode portion on the second segmented piezoelectric plate 11B to each other such that the first electrode 2 extends to the interior of the groove or is at a portion outside the groove.

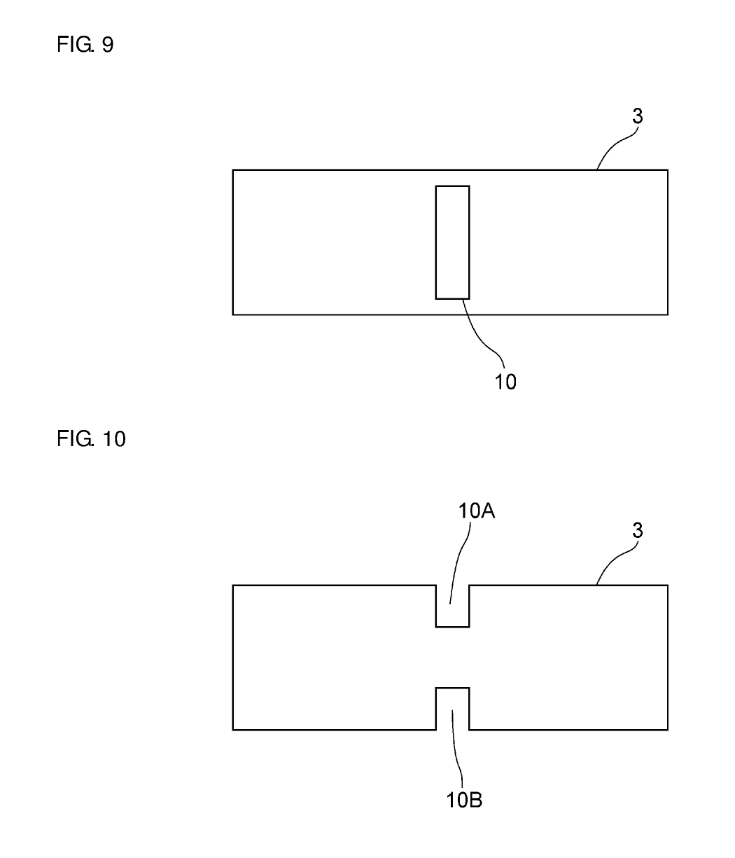

In the first to fourth preferred embodiments described above, the groove 10 is provided over the entire width of the first package substrate 3 in the widthwise direction so as to segment the same. However, as shown in FIG. 9 as a bottom view, the groove 10 may be shorter than the widthwise dimension of the first package substrate 3. That is, one end and the other end of the groove 10 may be positioned inwardly of one widthwise end and the other widthwise end of the first package substrate 3 in the widthwise direction. Moreover, as shown in FIG. 10, a groove 10A extending from the one widthwise end of the first package substrate 3 and a groove 10B extending from the other widthwise end thereof may be provided. As such, the groove 10 may not penetrate the first package substrate 3 in the widthwise direction.

Furthermore, the groove 10 may extend to the position indicated by the broken line C in FIG. 2 in the first package substrate 3, that is, so as not to extend to the principal surface of the first package substrate 3 on the piezoelectric element 2 side. That is, the groove 10 may have an arbitrary depth extending in a direction across the substrate, from the principal surface of the first package substrate 3 on the substrate 15 side.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric deflection sensor comprising:
a piezoelectric element including:
a first piezoelectric plate including a first principal surface and a second principal surface opposing the first principal surface, having a rectangular, substantially rectangular, square, or substantially square plan shape, and having a polarization axis direction parallel or substantially parallel to the first and second principal surfaces and in a direction along any side of the plan shape;
a first electrode provided on the first principal surface of the first piezoelectric plate; and
a second electrode provided on the second principal surface of the first piezoelectric plate;
a first package substrate stacked on the first principal surface of the piezoelectric element;
a second package substrate stacked on the second principal surface of the piezoelectric element;
a first bonding material layer bonding the first package substrate onto the first principal surface of the first piezoelectric plate; and
a second bonding material layer bonding the second package substrate onto the second principal surface of the first piezoelectric plate; wherein
one of the first electrode and the second electrode includes first and second segmented electrodes arranged along the polarization axis direction across a first electrode non-formation region extending in a direction intersecting the polarization axis direction, and the other of the first electrode and the second electrode opposes the first and second segmented electrodes and the first electrode non-formation region across the first piezoelectric plate; and
a groove extending in a direction intersecting the polarization axis direction in the first package substrate is provided at a position overlapping with at least a portion of the first electrode non-formation region in plan view.

2. The piezoelectric deflection sensor according to claim 1, wherein the first electrode non-formation region extends in a direction perpendicular or substantially perpendicular to the polarization axis direction.

3. The piezoelectric deflection sensor according to claim 1, wherein the groove extends in a direction perpendicular or substantially perpendicular to the polarization axis direction.

4. The piezoelectric deflection sensor according to claim 1, wherein the first and second segmented electrodes are provided on the first principal surface of the first piezoelectric plate.

5. The piezoelectric deflection sensor according to claim 1, wherein the first and second segmented electrodes are provided on the second principal surface of the first piezoelectric plate.

6. The piezoelectric deflection sensor according to claim 1, wherein the groove is positioned at a center or an approximate center of the first package substrate in the polarization axis direction.

7. The piezoelectric deflection sensor according to claim 1, wherein the groove extends to the piezoelectric element from the first package substrate.

8. The piezoelectric deflection sensor according to claim 1, wherein the groove extends to the second package substrate.

9. The piezoelectric deflection sensor according to claim 1, further comprising:
a second piezoelectric plate stacked on the second principal surface of the first piezoelectric plate, a polarization axis direction of the second piezoelectric plate being a reverse direction to the polarization axis direction of the first piezoelectric plate; wherein
third and fourth segmented electrodes arranged across a second electrode non-formation region in the polarization axis direction of the second piezoelectric plate are provided on a surface of the second piezoelectric plate on the second package substrate side.

10. The piezoelectric deflection sensor according to claim 1, the first piezoelectric plate has a rectangular or substantially rectangular plan shape.

11. The piezoelectric deflection sensor according to claim 1, the first piezoelectric plate is made of piezoelectric ceramics.

12. The piezoelectric deflection sensor according to claim 11, the piezoelectric ceramics are PZT or a piezoelectric single crystal.

13. The piezoelectric deflection sensor according to claim 1, wherein the first and second electrodes are made of Cu, Ag, Al or Au or alloy thereof.

14. The piezoelectric deflection sensor according to claim 1, wherein a width of the second electrode is narrower than a width of the first piezoelectric plate.

15. The piezoelectric deflection sensor according to claim 14, wherein one widthwise end and another widthwise end of the second electrode are respectively positioned inwardly of one widthwise end and another widthwise end of the first piezoelectric plate.

16. The piezoelectric deflection sensor according to claim 1, wherein the groove extends entirely through the first package substrate.

17. The piezoelectric deflection sensor according to claim 1, wherein a dimension of the first package substrate along a widthwise direction of the piezoelectric element is the same or substantially the same as a dimension of the piezoelectric element along the widthwise direction.

18. The piezoelectric deflection sensor according to claim 1, wherein the first package substrate is made of insulative ceramics.

19. The piezoelectric deflection sensor according to claim 18, wherein the insulative ceramics are alumina or magnesium titanate.

20. The piezoelectric deflection sensor according to claim 1, wherein a dimension of the groove in a widthwise direction of the first package substrate is smaller than a dimension of the first package substrate in the widthwise direction.
